(19) United States
(12) Patent Application Publication
(10) Pub. No.: US 2020/0128700 A1
(43) Pub. Date: Apr. 23, 2020

(54) DISPLAY DEVICE

(71) Applicant: Samsung Display Co., Ltd., Yongin-Si (KR)

(72) Inventors: Jee-na LEE, Anyang-si (KR); Min-gwan HYUN, Suwon-si (KR)

(21) Appl. No.: 16/549,592

(22) Filed: Aug. 23, 2019

(30) Foreign Application Priority Data
Oct. 17, 2018 (KR) 10-2018-0123511

(51) Int. Cl. H05K 7/20; F21V 8/00; H05K 5/02; H05K 5/00

(52) U.S. Cl. CPC H05K 7/20963; G02B 6/0085; G02B 6/005; H05K 5/0017; H05K 5/0204

(57) ABSTRACT

A display device includes a display module, in which a first region and a second region adjacent to the first region are defined, a heat-dissipation part disposed on a rear surface of the first region of the display module, a supporting part disposed on a rear surface of the second region of the display module, and a fastening part directly coupled to the heat-dissipation part and the supporting part.

This application claims priority to Korean Patent Application No. 10-2018-0123511, filed on Oct. 17, 2018, and all the benefits accruing therefrom under 35 U.S.C. § 119, the content of which in its entirety is herein incorporated by reference.

### BACKGROUND

### 1. Field

Exemplary embodiments of the invention relate to a display device, and in particular, to a display device to be mounted on a wall.

### 2. Description of the Related Art

A display device generally includes a display panel, which is used to display contents. Recently, there is an increasing demand for a high resolution, large-sized display panel. In addition, a thickness and a weight of a display device are being decreased, and such a thin and lightweight display device may be mounted on a wall.

### SUMMARY

A wall mount bracket is used to mount a display device to a wall. In a case where the display device is mounted on the wall using the wall mount bracket, a set cover space for connection with the wall mount bracket is needed. In addition, it is necessary to separate the display device from the wall by a thickness of the wall mount bracket, and this leads to deterioration in aesthetic appearance of the display device.

An exemplary embodiment of the invention provides a display device to be disposed (e.g., mounted) on a wall.

According to an exemplary embodiment of the invention, a display device may include a display module, in which a first region and a second region adjacent to the first region are defined, a heat-dissipation part disposed on a rear surface of the first region of the display module, a supporting part disposed on a rear surface of the second region of the display module, and a fastening part directly coupled to the heat-dissipation part and the supporting part.

In an exemplary embodiment, the display module may include a display panel which displays an image, a light conversion member disposed below the display panel, a light source part which provides light to the light conversion member, and a back chassis disposed below the light source part and the light conversion member. The heat-dissipation part may be in contact with the light source part and the fastening part.

In an exemplary embodiment, the heat-dissipation part may include a first heat-dissipation part in contact with the light source part, a second heat-dissipation part extended from the first heat-dissipation part and disposed below the back chassis. The fastening part may be coupled to the second heat-dissipation part.

In an exemplary embodiment, the light conversion member may include a light-guiding part and a light conversion layer, which is disposed on the light-guiding part and changes a wavelength of the light. The light source part may face a side surface the light-guiding part.

In an exemplary embodiment, the fastening part may include a first fastening part facing the heat-dissipation part, a second fastening part facing the supporting part, and a third fastening part protruding from the first fastening part toward the second heat-dissipation part. The first fastening part may be in contact with the second heat-dissipation part.

In an exemplary embodiment, the second heat-dissipation part may define a groove, in which the third fastening part is disposed, and the groove extends in a first direction.

In an exemplary embodiment, the supporting part may include a first supporting part, a second supporting part, which is extended from and across the first supporting part, and a third supporting part, which is spaced apart from and parallel to the first supporting part.

In an exemplary embodiment, the supporting part may define a first coupling region, in which the first supporting part and the second supporting part are coupled to each other, and a second coupling region, in which the second supporting part and the third supporting part are coupled to each other. The second fastening part may define openings, which are defined at regions facing the first coupling region and the second coupling region.

In an exemplary embodiment, the first supporting part may define a first hole, the third supporting part may define a second hole. The second fastening part may include a first fastening support part, which is coupled to the first hole, and a second fastening support part, which is coupled to the second hole.

In an exemplary embodiment, the heat-dissipation part may further include a plurality of protrusion parts protruding from the second heat-dissipation part. The first fastening part may define a plurality of reception parts in which the plurality of protrusion parts is respectively disposed in a one-to-one manner.

In an exemplary embodiment, the display device may further include at least one magnet disposed between the back chassis and the fastening part.

3

In an exemplary embodiment, an area of the display module may be larger than an area of the fastening part.

In an exemplary embodiment, the display device may further include a driving part, which is electrically connected to the display panel and is in contact with the heat-dissipation part.

In an exemplary embodiment, the fastening part may include a first fastening part facing the heat-dissipation part and a second fastening part facing the supporting part. The first fastening part may define a fastening opening, the second heat-dissipation part may include a heat-dissipation protrusion protruding toward the fastening opening, and the heat-dissipation protrusion may be coupled to the fastening opening.

In an exemplary embodiment, the display device may further include an exterior module electrically connected to the display module.

According to an exemplary embodiment of the invention, a display device may include a display panel which displays an image, a light source part which provides light to the display panel, a back chassis disposed below the light source part and the display panel, a heat-dissipation part including a first heat-dissipation part, which is in contact with the light source part, and a second heat-dissipation part, which is extended from the first heat-dissipation part and is disposed on a rear surface of the back chassis, and a fastening part disposed below the back chassis and coupled to the second heat-dissipation part.

In an exemplary embodiment, the display device may further include at least one magnet disposed between the fastening part and the back chassis.

In an exemplary embodiment, the display device may further include a supporting part disposed between the back chassis and the fastening part. The supporting part may be coupled to the fastening part.

In an exemplary embodiment, the heat-dissipation part may further include a plurality of protrusion parts protruding from the second heat-dissipation part, and the fastening part may define a plurality of reception parts in which the plurality of protrusion parts is respectively disposed in a one-to-one manner.

In an exemplary embodiment, the supporting part may include a first supporting part, a second supporting part, which is extended from and across the first supporting part, and a third supporting part, which is spaced apart from and parallel to the first supporting part. The first supporting part may define a first hole, the third supporting part may define a second hole, and the fastening part may include a first fastening support part coupled to the first hole and a second fastening support part coupled to the second hole.

### BRIEF DESCRIPTION OF THE DRAWINGS

Exemplary embodiments will be more clearly understood from the following brief description taken in conjunction with the accompanying drawings, in which:

FIG. 1 is a front view illustrating an exemplary embodiment of a display device according to the invention.

FIG. 2 is a perspective view illustrating an exemplary embodiment of a display device according to the invention.

FIG. 3 is an exploded perspective view illustrating an exemplary embodiment of a display device according to the invention.

FIG. 4 is a side view illustrating an exemplary embodiment of a display device according to the invention.

FIG. 5 is a cross-sectional view taken along line A-A′ of FIG. 2.

FIG. 6 is a cross-sectional view taken along line B-B′ of FIG. 2.

FIG. 7 is a perspective view illustrating an enlarged shape of a portion taken along line B-B′ of FIG. 2.

FIG. 8 is a perspective view taken along line C-C′ of FIG. 2.

FIG. 9 is a perspective view illustrating an exemplary embodiment of a cut portion of a display device according to the invention.

FIG. 10 is a perspective view illustrating an exemplary embodiment of a cut portion of a display device according to the invention.

FIGS. 11A and 11B are front views illustrating an exemplary embodiment of a shape of a display device according to the invention, when viewed in a second direction.

### DETAILED DESCRIPTION

Exemplary embodiments of the invention will now be described more fully with reference to the accompanying drawings, in which exemplary embodiments are shown. Exemplary embodiments of the invention may, however, be embodied in many different forms and should not be construed as being limited to the exemplary embodiments set forth herein; rather, these exemplary embodiments are provided so that this invention will be thorough and complete, and will fully convey the concept of exemplary embodiments to those of ordinary skill in the art. It should be noted that the drawing figures are intended to illustrate the general characteristics of methods, structure and/or materials utilized in certain exemplary embodiments and to supplement the written description provided below. These drawings are not, however, to scale and may not precisely reflect the precise structural or performance characteristics of any given embodiment, and should not be interpreted as defining or limiting the range of values or properties encompassed by exemplary embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the drawing figures. It will be understood that the spatially relative terms are intended to encompass different orientations of the device in use or operation in addition to the orientation depicted in the drawing figures. For example, if the device in the drawing figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof

Exemplary embodiments of the invention are described herein with reference to cross-sectional illustrations that are schematic illustrations of idealized embodiments (and intermediate structures) of exemplary embodiments. As such, variations from the shapes of the illustrations as a result, for example, of manufacturing techniques and/or tolerances, are to be expected. Thus, exemplary embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which exemplary embodiments of the invention belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein

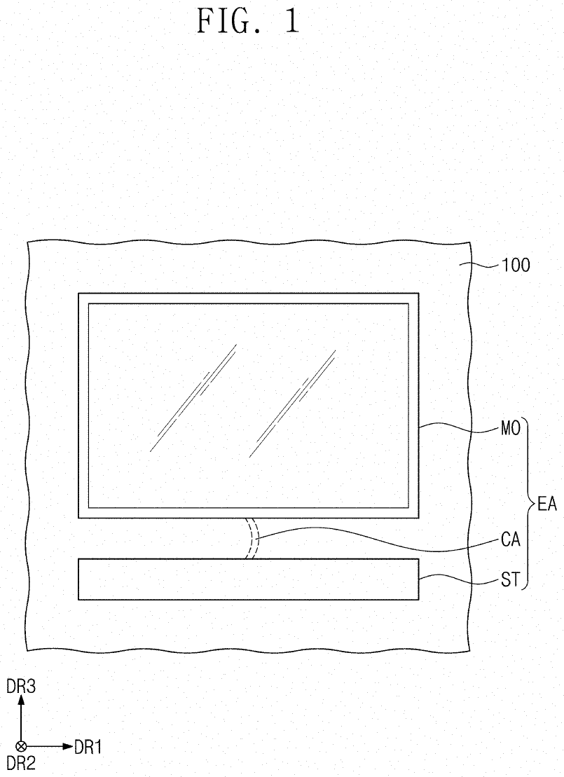

FIG. 1 is a front view illustrating an exemplary embodiment of a display device according to the invention.

Referring to FIG. 1, a display device EA may be activated by an electrical signal. The display device EA may include various exemplary embodiments. The display device EA may include an electronic device, such as televisions, monitors, or outdoor billboards. In the illustrated exemplary embodiment, a wall-mounting type television is illustrated as an example of the display device EA.

The display device EA may include a display module MO, a cable CA, and an exterior module ST. The display module MO and the exterior module ST may be fastened to a wall 100. In an exemplary embodiment, the exterior module ST may include an image board, a power, or a speaker, for example. The exterior module ST and the display module MO may be electrically connected to each other by the cable CA. The cable CA may not be exposed to the outside. In an exemplary embodiment, the cable CA may be disposed in the wall 100, for example. However, the invention is not limited to this example, and in another exemplary embodiment, the cable CA may be exposed to the outside. Furthermore, in another exemplary embodiment, the exterior module ST may be omitted. In this case, components included in the exterior module ST may be disposed in the display module MO.

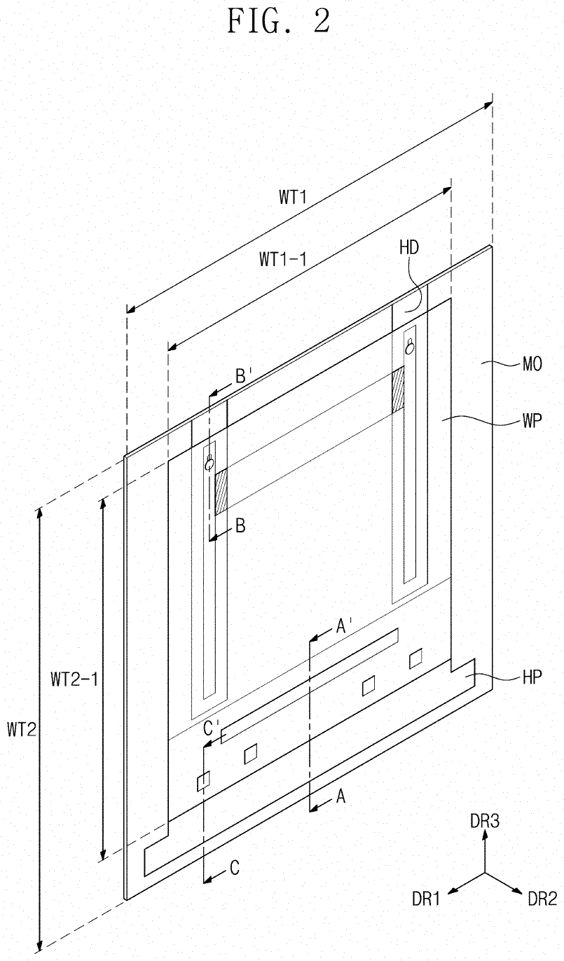

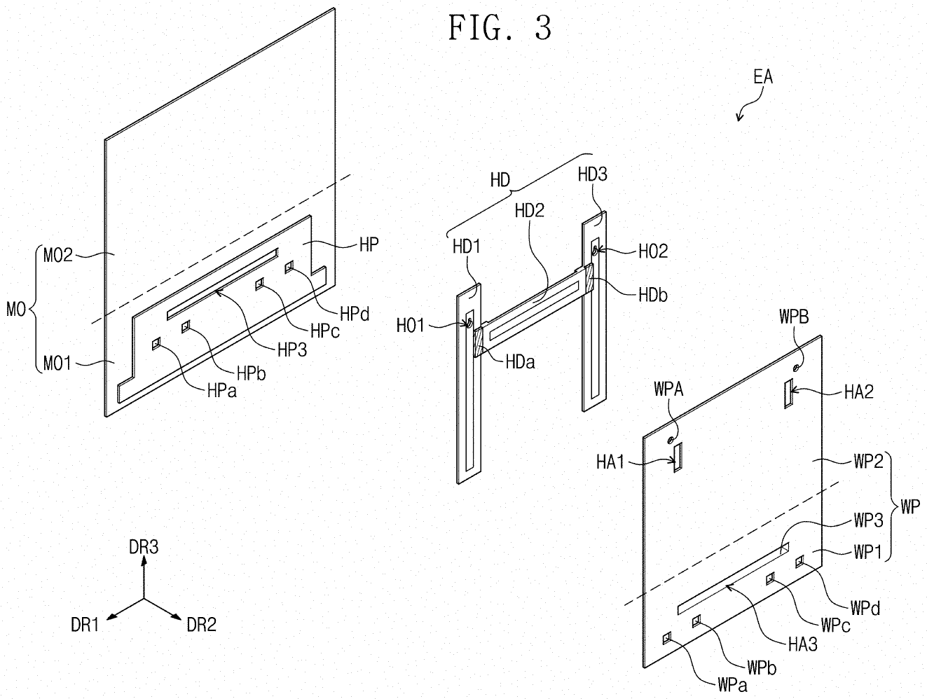

FIG. 2 is a perspective view illustrating a display device according to an exemplary embodiment of the invention, and FIG. 3 is an exploded perspective view illustrating a display device according to an exemplary embodiment of the invention.

Referring to FIGS. 2 and 3, the display device EA may include a display module MO, a heat-dissipation part HP, a supporting part HD, and a fastening part WP.

The display module MO may include a front surface serving as a display surface. The display surface may be defined to be parallel to a first direction DR1 and a third direction DR3. A direction normal to the display surface may be referred to a thickness direction DR2 (hereinafter, a second direction) of the display module MO.

In the description, directions indicated by the first to third directions DR1, DR2, and DR3 may be relative concept, and in an exemplary embodiment, they may be used to indicate other directions. Hereinafter, first to third directions may be directions indicated by the first to third directions DR1, DR2, and DR3, respectively, and will be referenced with the same numerals. In the description, a surface defined by the first direction DR1 and the third direction DR3 may be referred to as a “plane”, and an expression “in a plan view” may mean that an object to be described is seen in the second direction DR2.

The display module MO may include a first region MO1 and a second region MO2. The first region MO1 and the second region MO2 may be adjacent to each other. In an exemplary embodiment, the first region MO1 and the second region MO2 may be adjacent to each other in the third direction DR3, for example.

The heat-dissipation part HP may be disposed on a rear surface of the first region MO1 of the display module MO. The heat-dissipation part HP may transmit a heat energy, which is generated in the display module MO, to the outside. The heat-dissipation part HP may consist of or include at least one of metallic or metal alloy materials. In an exemplary embodiment, the heat-dissipation part HP may consist of or include a metallic material (e.g., aluminum) having high thermal conductivity, for example. However, the invention is not limited to the above material of the heat-dissipation part HP. In an exemplary embodiment, a thickness of the heat-dissipation part HP may range from about 1.0 millimeter (mm) to about 1.5 mm, for example, but the invention is not limited to the above thickness range of the heat-dissipation part HP.

The heat-dissipation part HP may include a first protrusion part HPa, a second protrusion part HPb, a third protrusion part HPc, and a fourth protrusion part HPd. The first to fourth protrusion parts HPa, HPb, HPc, and HPd may be arranged in the first direction DR1. In FIG. 2, the heat-dissipation part HP including four protrusion parts (e.g., HPa, HPb, HPc, and HPd) are illustrated as an exemplary embodiment of the invention, but the invention is not limited to this example. In an exemplary embodiment, the number of the protrusion parts may be less than or equal to three or may be larger than or equal to five, for example.

The supporting part HD may be disposed on a rear surface of the second region MO2 of the display module MO. When the display device EA is disposed (e.g., mounted) on the wall 100 (e.g., see FIG. 1), the supporting part HD may be disposed on the heat-dissipation part HP.

The supporting part HD may consist of or include at least one of metallic or metal alloy materials. The supporting part HD may consist of or include a metallic material having high stiffness. In an exemplary embodiment, the supporting part HD may consist of or include stainless steel, for example. However, the material of the supporting part HD is not limited to this example.

The supporting part HD may include a first supporting part HD1, a second supporting part HD2, and a third supporting part HD3. The first supporting part HD1 may extend in the third direction DR3. The second supporting part HD2 may extend in the first direction DR1 crossing the third direction DR3. The third supporting part HD3 may extend in the third direction DR3. The first supporting part HD1 may be parallel to the third supporting part HD3. In addition, the first supporting part HD1 may cross the second supporting part HD2. In an exemplary embodiment, the first supporting part HD1 may be perpendicular to the second supporting part HD2, for example. Thus, the supporting part HD may have an “H” shape in a plan view.

The third supporting part HD3 may be spaced apart from the first supporting part HD1. The second supporting part HD2 may be disposed between the first supporting part HD1 and the third supporting part HD3. The first supporting part HD1 and the second supporting part HD2 may be coupled to each other in a first coupling region HDa, and the second supporting part HD2 and the third supporting part HD3 may be coupled to each other in a second coupling region HDb.

A first hole HO1 may be defined in the first supporting part HD1. A second hole HO2 may be defined in the third supporting part HD3. Each of the first hole HO1 and the second hole HO2 may have a shape including a circular hole and a slit extended from the hole in the third direction DR3. The slit may be extended from the hole in the third direction DR3. However, the invention is not limited to this example, and in another exemplary embodiment, the shapes of the first hole HO1 and the second hole HO2 may be variously changed. In an exemplary embodiment, the first hole HO1 and the second hole HO2 may have a circular shape, for example.

Each of the first supporting part HD1, the second supporting part HD2, and the third supporting part HD3 may include an uneven portion, which has a concave or convex shape in the second direction DR2. Due to the uneven portion, the first supporting part HD1, the second supporting part HD2, and the third supporting part HD3 may have a high stiffness. A depth of the uneven portion may be smaller than a sum of thicknesses of the first supporting part HD1 and the second supporting part HD2 in the first coupling region HDa and a sum of thicknesses of the second supporting part HD2 and the third supporting part HD3 in the second coupling region HDb.

The fastening part WP may be disposed on rear surfaces of the heat-dissipation part HP and the supporting part HD. The fastening part WP may be coupled to the wall 100 (e.g., see FIG. 1). The fastening part WP may be coupled to the wall 100 by a screw (not shown), but the invention is not limited to a specific element for coupling the fastening part WP to the wall 100. In an exemplary embodiment, the fastening part WP may be coupled to the wall 100 with a rivet or an adhesive member or by a welding process, for example.

The fastening part WP may be coupled to the heat-dissipation part HP and may be in direct contact with the heat-dissipation part HP. Here, the expression “the fastening part WP may be in direct contact with the heat-dissipation part HP” may mean that the fastening part WP and the heat-dissipation part HP are in close contact with each other without any element interposed between the fastening part WP and the heat-dissipation part HP. Heat may be transferred to the fastening part WP from the heat-dissipation part HP. Thus, heat generated in the display module MO may be transferred to the fastening part WP through the heat-dissipation part HP, and this may make it possible to improve a heat-dissipation property of the display device EA. In addition, since the fastening part WP, along with the heat-dissipation part HP, are used to mount the display device EA on a wall, a separate set cover may be omitted from the rear surface of the display module MO. Thus, it may be possible to reduce a gap between the display device EA and the wall 100.

The fastening part WP may consist of or include at least one of metallic or metal alloy materials. In an exemplary embodiment, the fastening part WP may be selected from materials having high stiffness and high thermal conductivity, and in an exemplary embodiment, the fastening part WP may consist of or include stainless steel, for example. However, the invention is not limited to a specific material of the fastening part WP. A thickness of the fastening part WP may be smaller than a thickness of the heat-dissipation part HP. In an exemplary embodiment, the thickness of the fastening part WP may range from 0.8 mm to 1.0 mm, for example. However, the invention is not limited to a specific thickness of the fastening part WP.

The fastening part WP may include a first fastening part WP1, a second fastening part WP2, and a third fastening part WP3. The first fastening part WP1 may face the heat-dissipation part HP, and the second fastening part WP2 may face the supporting part HD. The third fastening part WP3 may protrude from the first fastening part WP1.

The first fastening part WP1 may include a first reception part WPa, a second reception part WPb, a third reception part WPc, and a fourth reception part WPd. The first to fourth reception parts WPa, WPb, WPc, and WPd may be arranged in the first direction DR1. The first to fourth protrusion parts HPa, HPb, HPc, and HPd may be respectively coupled to the first to fourth reception parts WPa, WPb, WPc, and WPd, for example, in a one-to-one manner. In an exemplary embodiment, the first protrusion part HPa may be disposed (e.g., contained) in and coupled to the first reception part WPa, the second protrusion part HPb may be disposed (e.g., contained) in and coupled to the second reception part WPb, the third protrusion part HPc may be disposed (e.g., contained) in and coupled to the third reception part WPc, and the fourth protrusion part HPd may be disposed (e.g., contained) in and coupled to the fourth reception part WPd, for example.

In FIG. 2, the fastening part WP with four reception parts (e.g., WPa, WPb, WPc, and WPd) are illustrated as an exemplary embodiment of the invention, but the invention is not limited to this example. In another exemplary embodiment, the number of the reception parts may be less than or equal to three or may be larger than or equal to five, for example.

A third opening HA3 may be defined in the first fastening part WP1. The third opening HA3 may extend in the first direction DR1. The third fastening part WP3 may protrude from the first fastening part WP1. The third fastening part WP3 may have a shape corresponding to a shape of the third opening HA3. In an exemplary embodiment, the third opening HA3 and the third fastening part WP3 may be provided by cutting and bending a portion of the first fastening part WP1, for example. The third fastening part WP3 may protrude toward the heat-dissipation part HP.

A first opening HA1 and a second opening HA2 may be defined in the second fastening part WP2. The first opening HA1 may face the first coupling region HDa, and the second opening HA2 may face the second coupling region HDb.

The first supporting part HD1 and the second supporting part HD2 may be coupled to each other in the first coupling region HDa. Thus, the first coupling region HDa may protrude toward the fastening part WP. Furthermore, the second supporting part HD2 and the third supporting part HD3 may be coupled to each other in the second coupling region HDb. Thus, the second coupling region HDb may protrude toward the fastening part WP. In an exemplary embodiment, the first opening HA1 and the second opening HA2 may be respectively defined in regions of the second fastening part WP2 corresponding to the protruding regions. Thus, the first coupling region HDa and the second coupling region HDb having the protruding shape may be respectively disposed (e.g., contained) in the first opening HA1 and the second opening HA2 in a one-to-one manner. Accordingly, the display module MO may be closely coupled to the fastening part WP.

The second fastening part WP2 may include a first fastening support part WPA and a second fastening support part WPB. Each of the first fastening support part WPA and the second fastening support part WPB may have a shape protruding toward the supporting part HD. The first fastening support part WPA may be disposed (e.g., contained) in the first hole HO1 defined in the supporting part HD and may be coupled with the supporting part HD. The second fastening support part WPB may be disposed (e.g., contained) in the second hole HO2 defined in the supporting part HD and may be coupled with the supporting part HD.

The fastening part WP may have an area smaller than that of the display module MO. Thus, the fastening part WP may not be seen to a user watching an image.

A length WT1 of the display module MO in the first direction DR1 may be greater than a length WT1-1 of the fastening part WP in the first direction DR1. A length WT2 of the display module MO in the third direction DR3 may be greater than a length WT2-1 of the fastening part WP in the third direction DR3. Thus, an area of the display module MO may be larger than an area of the fastening part WP.

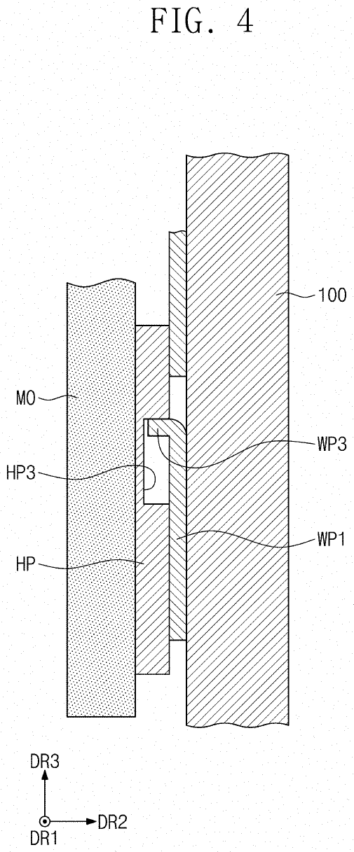

FIG. 4 is a side view illustrating a display device according to an exemplary embodiment of the invention. In the description of FIG. 4, an element previously described with reference to FIGS. 1 to 3 may be identified by the same reference number without repeating an overlapping description thereof

Referring to FIG. 4, a heat-dissipation hole HP3 may be defined in the heat-dissipation part HP. The third fastening part WP3 may be disposed (e.g., contained) in the heat-dissipation hole HP3.

The heat-dissipation hole HP3 and the third fastening part WP3 may extend in the first direction DR1. In an exemplary embodiment, a length of each of the heat-dissipation hole HP3 and the third fastening part WP3 may be greater than or equal to half a length of the display module MO in the first direction DR1, for example. A weight of the display module MO may be supported by the heat-dissipation hole HP3 and the third fastening part WP3.

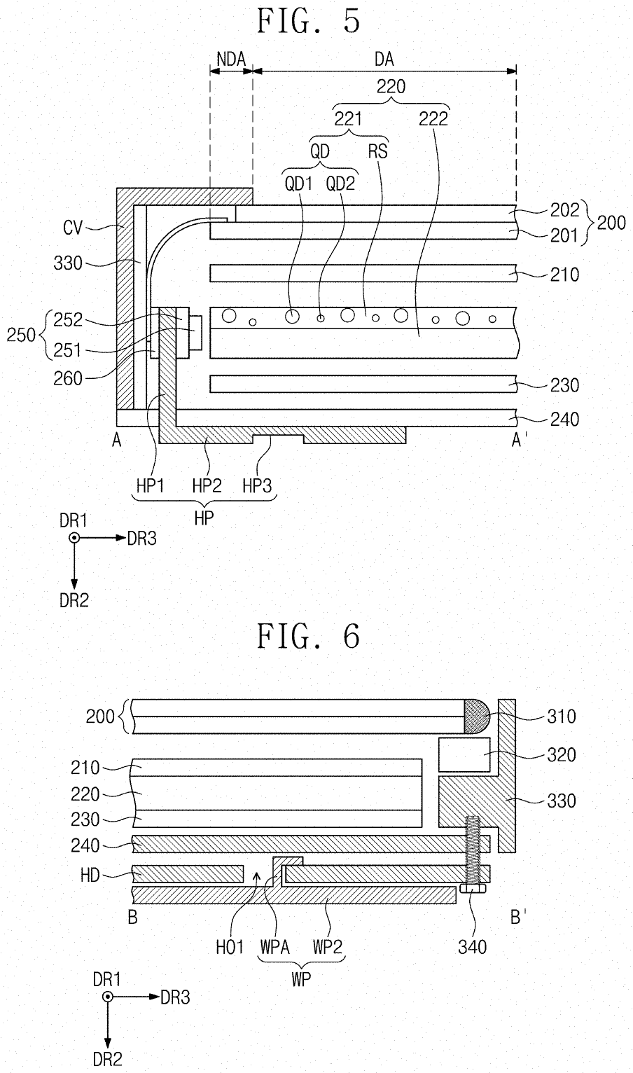

FIG. 5 is a cross-sectional view taken along line A-A′ of FIG. 2. For concise description, an element previously described with reference to FIGS. 1 to 4 may be identified by the same reference number without repeating an overlapping description thereof

Referring to FIG. 5, the display module MO (e.g., see FIG. 3) may include a display panel 200, an optical sheet 210, a light conversion member 220, a reflection part 230, a back chassis 240, a light source part 250, and a driving part 260.

The display panel 200 may display an image. In an exemplary embodiment, the display panel 200 may be one of a liquid crystal display panel, an electrowetting display panel, an electrophoretic display panel, and a micro electro mechanical system (“MEMS”) display panel, for example. The description that follows will refer to an example, in which a liquid crystal display panel is used as the display panel 200, but the invention is not limited to this example.

The display panel 200 may be a thin display panel. In an exemplary embodiment, a thickness of the display panel 200 may be less than about 3 mm, for example. However, the invention is not limited to a specific thickness of the display panel 200.

The display panel 200 may have a rectangular or tetragonal shape, whose sides are parallel to the first direction DR1 or the third direction DR3. However, the invention is not limited to this example, and in another exemplary embodiment, the shape of the display panel 200 may be variously changed. The display panel 200 may include a display substrate 201, an opposite substrate 202 facing the display substrate 201, and a liquid crystal layer (not shown) interposed between the display substrate 201 and the opposite substrate 202. In a plan view, the display panel 200 may include a display region DA, on which an image is displayed, and a non-display region NDA, which encloses the display region DA and does not display an image.

The non-display region NDA may be adjacent to the display region DA. The non-display region NDA may enclose the display region DA. Circuits or lines for driving the display region DA may be disposed in the non-display region NDA.

The optical sheet 210 may be disposed below the display panel 200. The optical sheet 210 may control a propagation path of light transmitted from the light conversion member 220. In an exemplary embodiment, the optical sheet 210 may include a diffusion sheet, a prism sheet, and a protection sheet, for example.

The diffusion sheet may diffuse light, and the prism sheet may allow the light diffused by the diffusion sheet to be propagated in a direction normal to the display panel DP or in a direction similar thereto. The protection sheet may protect the prism sheet from an external impact. In the illustrated exemplary embodiment, an example of the optical sheet 210 including one diffusion sheet, one prism sheet, and one protection sheet is illustrated, but the invention is not limited to this example. In another exemplary embodiment, in the optical sheet 210, at least one of the diffusion sheet, the prism sheet, and the protection sheet may be folded several times, for example, or, when necessary, may be omitted. In an exemplary embodiment, by forming a pattern and so forth in the light conversion member 220, it may be possible to allow the light conversion member 220 to have a function of the optical sheet 210.

The light conversion member 220 may guide light, which is provided from the light source part 250, toward the display panel 200. The light conversion member 220 may include a light conversion layer 221 and a light-guiding part 222.

The light-guiding part 222 may have a rectangular shape including two sides parallel to the first direction DR1, and other two sides parallel to the third direction DR3 crossing the first direction DR1. The light-guiding part 222 may receive light, which is provided from the light source part 250, and may guide the light toward the display panel 200. The light-guiding part 222 may consist of or include glass. In the case where the light-guiding part 222 consists of the glass, the light-guiding part 222 may have a good penetration-resistant property and thus may prevent an external moisture or air from passing therethrough. Furthermore, the light-guiding part 222 may protect the light conversion layer 221 from heat. However, the invention is not limited to this example, and in another exemplary embodiment, the light-guiding part 222 may consist of or include at least one of polyamide, polymethyl methacrylate, methyl methacrylate-styrene, or polycarbonate, for example.

The light conversion layer 221 may be disposed on a top surface of the light-guiding part 222. The light conversion layer 221 may lead to a change in wavelength of light, which is emitted from the light source part 250. In an exemplary embodiment, the light conversion layer 221 may convert a first light, which is transmitted from the light source part 250, to a second light, for example. In an exemplary embodiment, the light conversion layer 221 may convert a blue light, which is transmitted from the light source part 250, to a white light.

The light conversion layer 221 may include a light conversion material QD and a resin RS.

The resin RS may be a medium material, which is dispersed in the light conversion material QD, and may include at least one of various resin composites, which are in general referred to as “binder”. However, the invention is not limited to this example, and in another exemplary embodiment, when the light conversion material QD may be dispersed in a medium material, such a medium material may be referred to as a base resin, regardless of its name, additional function, or constituents. The base resin may be a polymer resin. In an exemplary embodiment, the base resin may be acrylic resins, urethane resins, silicone resins, and/or epoxy resins, for example. The base resin may be transparent.

In an exemplary embodiment, the light conversion material QD may consist of or include quantum dots. However, the invention is not limited to this example, and in another exemplary embodiment, a material or composition of the light conversion material QD may be variously changed. In an exemplary embodiment, the light conversion material QD may be a fluorescent element, for example, but the invention is not limited to this example or a specific exemplary embodiment.

To generate a white light, the light conversion material QD may include quantum dots of various sizes, depending on the kind of the light source part 250. In an exemplary embodiment, the light conversion material QD may include a first quantum dot QD1 and a second quantum dot QD2, for example. In the case where the light source part 250 generates a blue light, the first quantum dot QD1 may absorb a blue fraction of light incident thereto and emit a red light. The second quantum dot QD2 may absorb a blue fraction of the incident light and emit a green light.

Each of the quantum dots may have a nanometer-order crystalline material consisting of or including hundreds to thousands of atoms, and due to its small size, the quantum dots may exhibit an increase in band gap caused by the quantum confinement effect. In the case where an energy of light incident to the quantum dots is larger than a band gap of each of the quantum dots, each of the quantum dots may absorb the light to be in an excited state, and then, may emit light of a specific wavelength, while returning to its ground state. The wavelength of the emitted light may be determined by the band gap. That is, by adjusting sizes or compositions of the quantum dots, it may be possible to control a quantum confinement effect and light-emitting characteristics of the quantum dots.

The quantum dots may have a core-shell structure including a core and a shell enclosing the core. In an exemplary embodiment, the quantum dots may have a core/shell structure, in which one quantum dot is enclosed by another quantum dot. At an interface between the core and the shell, an element included (e.g., contained) in the shell may have a concentration gradient decreasing in a central direction.

Each of the quantum dots may be a nanometer-scale particle. Each of the quantum dots may have a light-emitting wavelength spectrum having full width half maximum (“FWHM”) less than about 45 nanometers (nm) (in particular, less than about 40 nm or in more particular, less than about 30 nm), and in this case, it may be possible to realize improved color purity or color reproduction characteristics. Furthermore, the quantum dots may allow light to be emitted radially, and thus, it may be possible to improve a viewing angle property.

In an exemplary embodiment, the quantum dots may be a spherical, pyramid-shaped, multi-arm, or cubic nano particle. In another exemplary embodiment, the quantum dots may be a nano tube, a nano wire, a nano fiber, a nano plate-shaped particle, but the invention is not limited to these examples.

The light conversion material QD of the light conversion layer 221 may absorb a blue light, which is provided from the light source part 250, and to convert it to a light of green or red band. Here, a fraction of the blue light may not be absorbed by the light conversion material QD. Thus, lights of blue, green, and red bands may be mixed in the light conversion layer 221 to generate a white light.

The light source part 250 may face a side surface of the light conversion member 220. In an exemplary embodiment, the light source part 250 may face a side surface of the light-guiding part 222, for example. The light source part 250 may provide light to the light conversion member 220. The light source part 250 may include a light source 251 and a printed circuit board (“PCB”) 252. The light source 251 may be disposed (e.g., mounted) on the PCB 252 and may receive a driving voltage from the PCB 252. In an exemplary embodiment, a plurality of the light sources 251 may be provided and may be, for example, arranged in the first direction DR1 on the PCB 252. The light source part 250 may be in contact with the heat-dissipation part HP. Thus, heat generated in the light source part 250 may be exhausted to the outside of the display module MO through the heat-dissipation part HP.

The heat-dissipation part HP may include a first heat-dissipation part HP1 and a second heat-dissipation part HP2. The first heat-dissipation part HP1 may extend in the second direction DR2. The second heat-dissipation part HP2 may extend in the third direction DR3. In an exemplary embodiment, the first heat-dissipation part HP1 may penetrate the back chassis 240 and may be disposed in the display module MO, for example. The PCB 252 may be in contact with the first heat-dissipation part HP1. The PCB 252 may be disposed on or near the first heat-dissipation part HP1, and in this case, heat, which is generated in the light source 251 and the PCB 252, may be transmitted to the first heat-dissipation part HP1. The second heat-dissipation part HP2 may be disposed on a rear surface of the display module MO.

The driving part 260 may be electrically connected to the display panel 200. The driving part 260 may control the display panel 200. The driving part 260 may be in contact with the heat-dissipation part HP. In an exemplary embodiment, the driving part 260 may be in contact with the first heat-dissipation part HP1, for example. Thus, heat generated in the driving part 260 may be exhausted to the outside through the heat-dissipation part HP. However, the invention is not limited to this example, and in another exemplary embodiment, the driving part 260 may be disposed below the second heat-dissipation part HP2 and may be in contact with the second heat-dissipation part HP2. However, the invention is not limited to this example or a specific exemplary embodiment.

The driving part 260 may be veiled by a cover part CV. The cover part CV may cover the non-display region NDA of the display panel 200.

The reflection part 230 may be disposed between the light conversion member 220 and the back chassis 240. The reflection part 230 may reflect light, which may be leaked from the light conversion member 220, toward the light conversion member 220.

The back chassis 240 may be disposed outside the display module MO and may protect the display module MO. The back chassis 240 may consist of or include at least one of metallic or metal alloy materials. In an exemplary embodiment, the back chassis 240 may consist of or include stainless steel, for example. However, the material of the back chassis 240 is not limited to this example.

FIG. 6 is a cross-sectional view taken along line B-B′ of FIG. 2. For concise description, an element previously described with reference to FIG. 5 may be identified by the same reference number without repeating an overlapping description thereof

Referring to FIG. 6, a print layer 310 may be disposed on a side surface of the display panel 200. The print layer 310 may have a black color. In general, the print layer 310 has an opaque black color, but in another exemplary embodiment, the color of the print layer 310 may be variously changed.

A frame part 330 may be disposed below the display panel 200. The frame part 330 and the display panel 200 may be coupled to each other by an adhesion part 320. In an exemplary embodiment, the adhesion part 320 may be a foam tape, for example. The frame part 330, the back chassis 240, and the supporting part HD may be coupled to each other by a plurality of screws 340. However, the invention is not limited to this example, and in another exemplary embodiment, the frame part 330, the back chassis 240 and the supporting part HD may be coupled to each other with a rivet or an adhesive tape or by a welding process, but the invention is not limited to these examples.

The first hole HO1 may be defined in the supporting part HD to penetrate the supporting part HD in the second direction DR2. The first hole HO1 may have a shape including a circular hole and a slit extended from the hole in the third direction DR3. The slit may be extended from the hole in a direction opposite to the gravitational force. However, the invention is not limited to this example, and the shape of the first hole HO1 may be variously changed. In an exemplary embodiment, the first hole HO1 may have a circular shape, for example.

The fastening part WP may further include the first fastening support part WPA, which is provided to protrude from the second fastening part WP2 in the second direction DR2. The first fastening support part WPA may be coupled to the first hole HO1. The first fastening support part WPA may be disposed (e.g., contained) in the first hole HO1 and may support weights of the display module MO (e.g., see FIG. 3) and the supporting part HD.

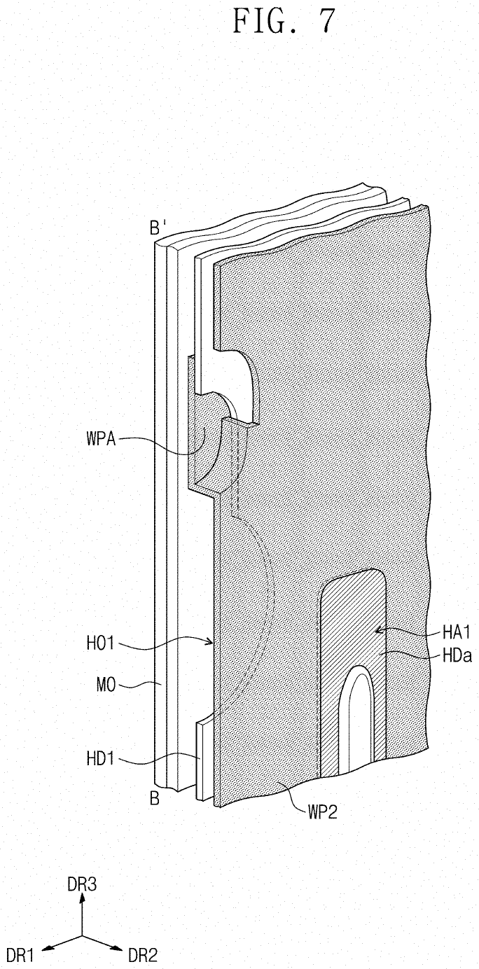

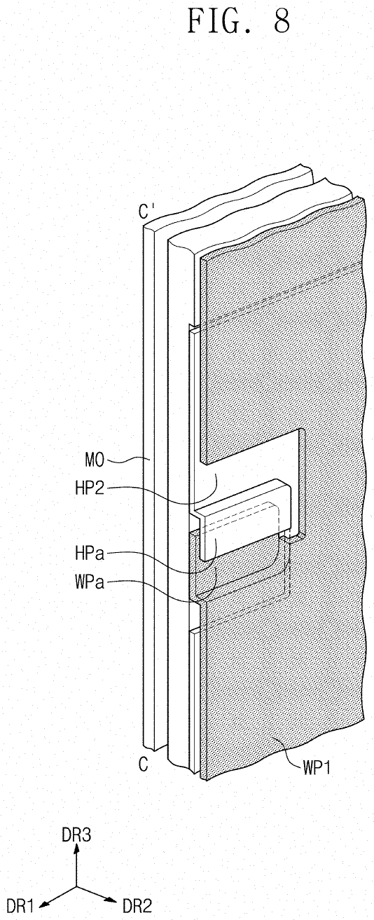

FIG. 7 is a perspective view illustrating an enlarged shape of a portion taken along line B-B′ of FIG. 2, and FIG. 8 is a perspective view taken along line C-C′ of FIG. 2. In the description of FIGS. 7 and 8, an element previously described with reference to FIGS. 1 to 6 may be identified by the same reference number without repeating an overlapping description thereof

Referring to FIG. 7, the first hole HO1 may be defined in the first supporting part HD1. The first hole HO1 may have a shape including a circular hole and a slit extended from the hole in the third direction DR3. The slit may be extended from the hole in a direction opposite to the gravitational force. The first fastening support part WPA protruding toward the first supporting part HD1 may be provided in the second fastening part WP2. The first fastening support part WPA may have a hook shape protruding from the second fastening part WP2 toward the first hole HO1. The first fastening support part WPA may be coupled to the first hole HO1. In an exemplary embodiment, the first fastening support part WPA may be inserted into the circular hole of the first hole HO1 and may be coupled with the slit, for example. The first fastening support part WPA may be coupled to the first hole HO1 and may prevent the display module MO from leaning in a front direction.

Referring to FIG. 8, the first protrusion part HPa of the heat-dissipation part HP (e.g., see FIG. 3) may be coupled to the first reception part WPa of the fastening part WP (e.g., see FIG. 3). In an exemplary embodiment, the first protrusion part HPa of the second heat-dissipation part HP2 may be coupled to the first reception part WPa of the first fastening part WP1, for example.

The first protrusion part HPa and the first reception part WPa may support a weight of the display module MO.

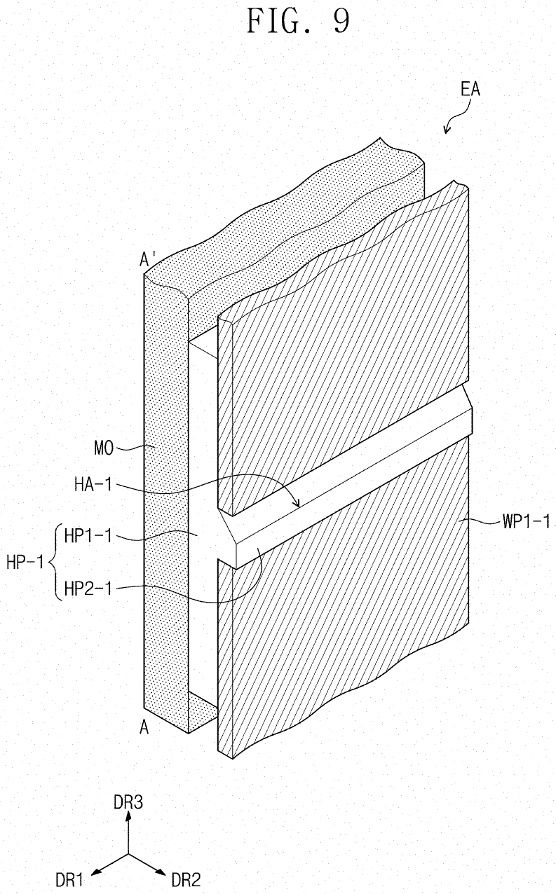

FIG. 9 is a perspective view illustrating a cut portion of a display device according to an exemplary embodiment of the invention. In an exemplary embodiment, a section shown in FIG. 9 may correspond to a section taken along line A-A′ of FIG. 2, for example.

Referring to FIG. 9, a heat-dissipation part HP-1 may include a first heat-dissipation part HP1-1 and a heat-dissipation protrusion HP2-1. The heat-dissipation protrusion HP2-1 may protrude from the first heat-dissipation part HP1-1 in the second direction DR2.

An opening HA-1 may be defined in a fastening part WP-1-1.

The heat-dissipation protrusion HP2-1 may be disposed (e.g., contained) in the opening HA-1. The heat-dissipation protrusion HP2-1 may be coupled to the opening HA-1 to support weights of the display module MO and the heat-dissipation part HP-1.

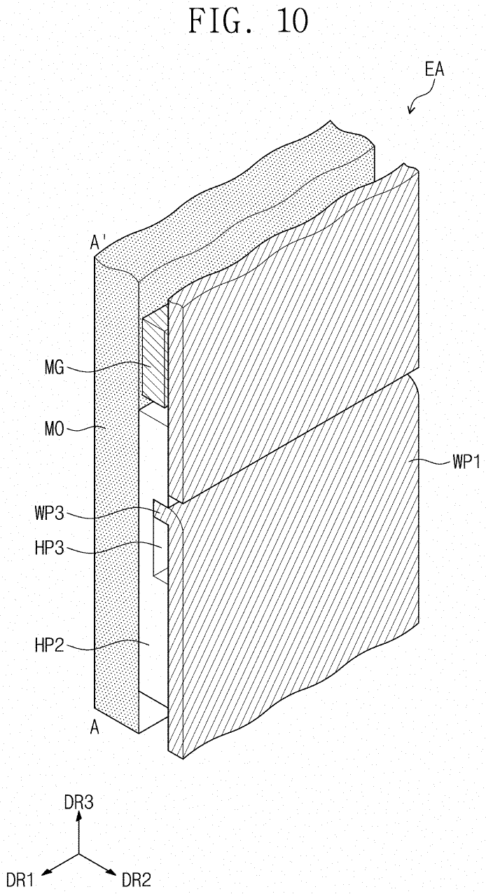

FIG. 10 is a perspective view illustrating a cut portion of a display device according to an exemplary embodiment of the invention. In an exemplary embodiment, a section shown in FIG. 10 may correspond to a section taken along line A-A′ of FIG. 2, for example.

Referring to FIGS. 5 and 10, the display device EA may include at least one magnet MG disposed between the display module MO and the fastening part WP. In an exemplary embodiment, the magnet MG may be attached to the back chassis 240 and the fastening part WP, for example.

The magnet MG may fasten the back chassis 240 and the fastening part WP using a magnetic force. In an exemplary embodiment, the magnet MG may have a rectangular or tetragonal shape, for example. However, the invention is not limited to this example, and in another exemplary embodiment, the shape of the magnet MG may be variously changed. In another exemplary embodiment, the magnet MG may have a circular shape, for example.

The magnet MG may include a soft plastic magnet, which is one of permanent magnets. The soft plastic magnet may be referred to as a rubber magnet. The rubber magnet may include an isotropic rubber magnet, an anisotropic rubber magnet, and a semi-anisotropic rubber magnet. However, the invention is not limited to this example, and in another exemplary embodiment, the magnet MG may include various magnets. In an exemplary embodiment, the magnet MG may include one of a neodymium magnet or a ferrite magnet, for example.

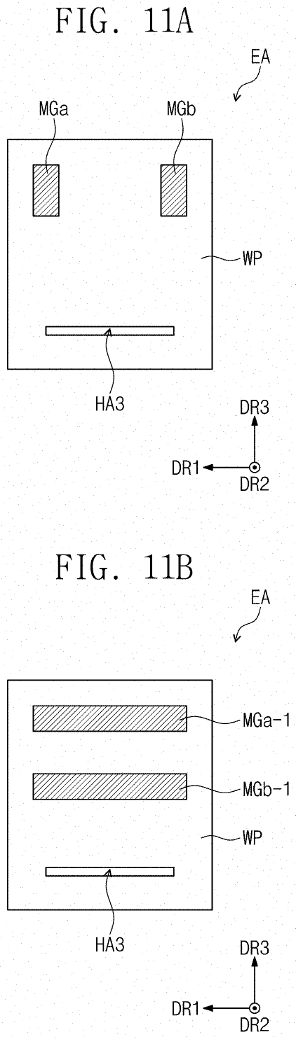

FIGS. 11A and 11B are front views illustrating a shape of a display device according to an exemplary embodiment of the invention, when viewed in a second direction. For concise description, an element previously described with reference to FIGS. 1 to 10 may be identified by the same reference number without repeating an overlapping description thereof.

Referring to FIG. 11A, the display device EA may include magnets MGa and MGb disposed between the display module MO (e.g., see FIG. 10) and the fastening part WP. However, the invention is not limited to this example, and in another exemplary embodiment, two or more magnets may be provided in the display device EA.

The magnets MGa and MGb may extend in the third direction DR3 and may be arranged in the first direction DR1. In an exemplary embodiment, the first magnet MGa may extend in the third direction DR3, for example. The second magnet MGb may be spaced apart from the first magnet MGa in the first direction DR1. The first magnet MGa may be parallel to the second magnet MGb.

Referring to FIG. 11B, the magnets MGa-1 and MGb-1 may extend in the first direction DR1 and may be arranged in the third direction DR3. In an exemplary embodiment, the third magnet MGa-1 may extend in the first direction DR1, for example. The fourth magnet MGb-1 may be spaced apart from the third magnet MGa-1 in the third direction DR3. The third magnet MGa-1 may be parallel to the fourth magnet MGb-1. However, the invention is not limited to this example, and in another exemplary embodiment, the magnets may be variously arranged.

According to an exemplary embodiment of the invention, a fastening part to be fixed to a wall may be coupled and contacted to a heat-dissipation part. Thus, heat generated in a display module may be transferred to the fastening part through the heat-dissipation dissipation part. This may make it possible to improve a heat-dissipation property of a display device. In addition, the fastening part, along with the heat-dissipation part, are used to mount a display device to a wall, a separate set cover may be omitted from a rear surface of the display module. Thus, it may be possible to reduce a gap between the display device and the wall.

While exemplary embodiments of the invention have been particularly shown and described, it will be understood by one of ordinary skill in the art that variations in form and detail may be made therein without departing from the spirit and scope of the attached claims.

What is claimed is:

1. A display device, comprising:
a display module, in which a first region and a second region adjacent to the first region are defined;
a heat-dissipation part disposed on a rear surface of the first region of the display module;
a supporting part disposed on a rear surface of the second region of the display module; and
a fastening part directly coupled to the heat-dissipation part and the supporting part.

2. The display device of claim 1, wherein the display module comprises:
a display panel which displays an image;
a light conversion member disposed below the display panel;
a light source part which provides light to the light conversion member; and
a back chassis disposed below the light source part and the light conversion member,
wherein the heat-dissipation part is in contact with the light source part and the fastening part.

3. The display device of claim 2, wherein the heat-dissipation part comprises:
a first heat-dissipation part in contact with the light source part;
a second heat-dissipation part extended from the first heat-dissipation part and disposed below the back chassis,
wherein the fastening part is coupled to the second heat-dissipation part.

4. The display device of claim 2, wherein the light conversion member comprises:
a light-guiding part; and
a light conversion layer which is disposed on the light-guiding part and changes a wavelength of the light,
wherein the light source part faces a side surface the light-guiding part.

5. The display device of claim 3, wherein the fastening part comprises a first fastening part facing the heat-dissipation part, a second fastening part facing the supporting part, and a third fastening part protruding from the first fastening part toward the second heat-dissipation part, and
the first fastening part is in contact with the second heat-dissipation part.

6. The display device of claim 5, wherein the second heat-dissipation part defines a groove, in which the third fastening part is disposed, and
the groove extends in a first direction.

7. The display device of claim 5, wherein the supporting part comprises a first supporting part, a second supporting part, which is extended from and across the first supporting part, and a third supporting part, which is spaced apart from and parallel to the first supporting part.

8. The display device of claim 7, wherein the supporting part defines a first coupling region, in which the first supporting part and the second supporting part are coupled to each other, and a second coupling region, in which the second supporting part and the third supporting part are coupled to each other, and
the second fastening part defines openings, which are defined at regions facing the first coupling region and the second coupling region.

9. The display device of claim 7, wherein the first supporting part defines a first hole,
the third supporting part defines a second hole, and
the second fastening part comprises a first fastening support part, which is coupled to the first hole, and a second fastening support part, which is coupled to the second hole.

10. The display device of claim 5, wherein the heat-dissipation part further comprises a plurality of protrusion parts protruding from the second heat-dissipation part, and
the first fastening part defines a plurality of reception parts in which the plurality of protrusion parts is respectively disposed in a one-to-one manner.

11. The display device of claim 2, further comprising at least one magnet disposed between the back chassis and the fastening part.

12. The display device of claim 1, wherein an area of the display module is larger than an area of the fastening part.

13. The display device of claim 2, further comprising a driving part, which is electrically connected to the display panel and is in contact with the heat-dissipation part.

14. The display device of claim 3, wherein the fastening part comprises a first fastening part facing the heat-dissipation part and a second fastening part facing the supporting part,
the first fastening part defines a fastening opening,
the second heat-dissipation part comprises a heat-dissipation protrusion protruding toward the fastening opening, and
the heat-dissipation protrusion is coupled to the fastening opening.

15. The display device of claim 1, further comprising an exterior module electrically connected to the display module.

16. A display device, comprising:
a display panel which displays an image;
a light source part which provides light to the display panel;
a back chassis disposed below the light source part and the display panel;
a heat-dissipation part comprising a first heat-dissipation part, which is in contact with the light source part, and a second heat-dissipation part, which is extended from the first heat-dissipation part and is disposed on a rear surface of the back chassis; and
a fastening part disposed below the back chassis and coupled to the second heat-dissipation part.

17. The display device of claim 16, further comprising at least one magnet disposed between the fastening part and the back chassis.

18. The display device of claim 16, further comprising a supporting part disposed between the back chassis and the fastening part,
wherein the supporting part is coupled to the fastening part.

19. The display device of claim 18, wherein the heat-dissipation part further comprises a plurality of protrusion parts protruding from the second heat-dissipation part, and
the fastening part defines a plurality of reception parts in which the plurality of protrusion parts is respectively disposed in a one-to-one manner.

20. The display device of claim 18, wherein the supporting part comprises a first supporting part, a second supporting part, which is extended from and across the first supporting part, and a third supporting part, which is spaced apart from and parallel to the first supporting part,
the first supporting part defines a first hole,
the third supporting part defines a second hole, and
the fastening part comprises a first fastening support part coupled to the first hole and a second fastening support part coupled to the second hole.
